(19) United States
(12) Patent Application Publication
(10) Pub. No.: US 2006/0255335 A1
(43) Pub. Date: Nov. 16, 2006

(54) Method for manufacturing semiconductor element, semiconductor element, and semiconductor device

(75) Inventors: Takao Nishikawa, Shiojiri-shi (JP); Satoshi Ogawa, Morioka-shi (JP); Noriyuki Yoshimoto, Morioka-shi (JP); Shinichiro Kobayashi, Sendai-shi (JP); Yoshihiro Iwasa, Sendai-shi (JP)

Correspondence Address: OLIFF & BERRIDGE, PLC, P.O. BOX 19928, ALEXANDRIA, VA, 22320, US

(73) Assignee: SEIKO EPSON CORPORATION, TOKYO (JP)

(21) Appl. No.: 11/391,554

(22) Filed: Mar. 29, 2006

(30) Foreign Application Priority Data
Mar. 29, 2005 (JP) 2005-094436

(51) Int. Cl. H01L 29/08; H01L 21/00

(52) U.S. Cl. 257/40; 438/82; 257/410; 438/216; 257/E51.007

(57) ABSTRACT

A method for manufacturing a semiconductor element in which a characteristic control layer for controlling a threshold voltage of the semiconductor element interposed in between an organic-semiconductor layer facing to a gate electrode across an insulating layer, and the insulating layer, the method comprising: selecting a density of the characteristic control layer depending on a threshold voltage of the semiconductor element; and forming the characteristic control layer of the density selected in the selection step.

### BACKGROUND

1. Technical Field

The present invention relates to semiconductor elements using an organic semiconductor material (hereinafter, referred to as the “organic-semiconductor material”).

2. Related Art

Conventionally, there have been proposed techniques in which semiconductor elements, such as a thin film transistor, are formed using an organic-semiconductor material, such as pentacene and fullerene, as a semiconductor layer. This type of semiconductor element has various advantages that, as compared with semiconductor elements made of inorganic material such as silicon, a lot of semiconductor layers can be produced with an inexpensive technique, such as a printing method, and moreover semiconductor layers can be formed under normal temperature even in the surface of a flexible plate such as plastics.

Now, in the semiconductor element including semiconductor layers made of an inorganic material, the threshold voltage of semiconductor elements can be controlled precisely by controlling the impurity doping amount with respect to the semiconductor layer. However, in the semiconductor element using an inorganic semiconductor material, there is a problem that it is difficult to control the threshold voltage by doping impurities. According to the examples of related art, in order to solve this problem, for example, a configuration is disclosed in which a film (hereinafter, referred to as the “threshold-voltage control film”) made of a silane compound or the like is interposed in between a gate insulating layer and a semiconductor layer. According to this configuration, the threshold voltage of the semiconductor element can be adjusted by selecting the material of the threshold-voltage control film suitably.

JP-A-2005-32774 (Paragraph 0025 and FIG. 1) is an example of the related art. NATUREMATERIALS, 3, 317 (2004) is a second example of the related art.

However, because the threshold voltage of the semiconductor element differs greatly depending on the material of the threshold-voltage control film, it is difficult to precisely control the threshold voltage in the unit of approximately several voltages under this technique. Moreover, because the material of the threshold-voltage control film is restricted to a specific material depending on the threshold voltage required in the practical use of the semiconductor element, the design flexibility of the semiconductor element may be restricted.

### SUMMARY

An advantage of the invention is to solve the problem that the threshold voltage of the semiconductor element using an organic-semiconductor material is controlled precisely.

As the result of research on the semiconductor element using an organic-semiconductor material, the present inventor obtained a knowledge that the threshold voltage of the semiconductor element varies depending on the density of a film (hereinafter, referred to as the “characteristic control layer”) formed in between an insulating layer and a semiconductor layer. According to an aspect of the invention, a method for manufacturing a semiconductor element in which the characteristic control layer for controlling a threshold voltage of a semiconductor element interposed in between an organic-semiconductor layer facing to a gate electrode across an insulating layer, and the insulating layer, the method includes: a selection step for selecting a density of the characteristic control layer depending on a threshold voltage of the semiconductor element; and a film formation step for forming the characteristic control layer of the density selected in the selection step. According to this method, because the threshold voltage of the semiconductor element is adjusted depending on the density of the characteristic control layer, the threshold voltage of the semiconductor element can be controlled precisely as compared with the method of adjusting the threshold voltage depending on the material of the semiconductor layer. However, in addition to the adjustment of the threshold voltage depending on the density of the characteristic control layer like the invention, the threshold voltage may be adjusted by selecting the material of the semiconductor layer.

Now, substance such as a silane compound (especially, self-assembled monolayer made of a silane compound) exhibits a characteristic that the density is saturated as the film formation proceeds. In forming the characteristic control layer using this kind of substance as the material, in the film formation step it is preferable to form the characteristic control layer having a density prior to saturation. According to this embodiment, because the density of the characteristic control layer can be controlled arbitrarily, the threshold voltage of the semiconductor element can be adjusted to a predetermined value accurately. In addition, the “saturation of density” in this embodiment means a state where the density of the characteristic control layer is maintained at a substantially constant value, regardless of the progress of the film formation. Nevertheless, in the “saturation” the density of the characteristic control layer is not necessarily maintained to be substantially constant. For example, even if the density of the characteristic control layer varies within a range from a first value to a second value, the density of the characteristic control layer is saturated if the difference between the threshold voltage of the semiconductor element in the density of the characteristic control layer of the first value, and the threshold voltage of the semiconductor element in the density of the characteristic control layer of the second value is such difference that will not cause a problem in the practical use of the semiconductor element.

As a method for controlling the density of the characteristic control layer, it is preferable that the film formation be terminated in a phase of before the density of the characteristic control layer is saturated. According to this method, because simplification of the film formation step and reduction of the time required are achieved, the manufacturing cost of the semiconductor element can be reduced. In addition, a specific example of this embodiment will be described later as a first method of controlling the density.

Then, in order to terminate the film formation in a phase of before the density of the characteristic control layer is saturated, it is necessary to identify this terminating time point in advance. As this specific method, a method can be considered in which the extent of processing of film formation of a film made of the same material as the characteristic control layer, and the density of the film are measured in advance, thereby detecting the phase in which the density is saturated. However, measurement of the density of the film may not necessarily be easy. In such a case, it is preferable that a relationship between a characteristic value other than the density of the film made of a predetermined material and the degree of the film formation be measured in advance, thereby estimating the phase in which the density is saturated. For example, it is preferable that a measurement step be carried out in advance in which a relationship between the extent of processing of film formation of a film made of a predetermined material, and the contact angle of liquid in the surface of the film is measured, thereby detecting a specific phase in which the contact angle is saturated with respect to the progress of the film formation, and that in the film formation step the film formation be terminated prior to the specific phase detected in the measurement step. It is also preferable that a measurement step be carried out in advance in which a relationship between the extent of processing of film formation of a film made of a predetermined material, and the film thickness of the film is measured, thereby detecting a specific phase in which the film thickness is saturated with respect to the progress of the film formation, and that in the film formation step the film formation be terminated prior to the specific phase detected in the measurement step. According to these methods, a time point when the film formation is to be terminated can be grasped easily.

Moreover, it is also preferable that as a method for controlling the density of the characteristic control layer, a first step for allowing the film formation to proceed until the density of the characteristic control layer is saturated, and a second step for applying a treatment to reduce the density with respect to the characteristic control layer formed in the first step be carried out in the film formation step. In addition, a specific example of this embodiment will be described later as a second density control method.

More specifically, it is preferable that the second step include at least one of a step for heating the characteristic control layer formed by the first step thereby to reduce the density thereof; a step for irradiating light at the characteristic control layer thereby to reduce the density thereof; and a step for soaking into an alkaline liquid the characteristic control layer thereby to reduce the density thereof. According to this embodiment, semiconductor elements whose threshold voltage differs can be easily formed, for example, by carrying out the second step individually to each of the semiconductor elements after forming a plurality of semiconductor elements in batches in the first step. In addition, in the case where a lot of semiconductor elements are formed in batches, the second step may be carried out selectively only to specific semiconductor elements among these semiconductor elements, or the second step may be carried out individually to the semiconductor elements of a certain region, and to the semiconductor elements of other regions.

Adjustment of the threshold voltage depending on the density of the characteristic control layer, and adjustment of the threshold voltage depending on a characteristic other than this may be carried out together. According to the research by the present inventor, a knowledge has been obtained that the threshold voltage of the semiconductor element differs depending on a molecule chain length of the material of the characteristic control layer. Therefore, it is also preferable that after carrying out a material selection step for selecting the material of the molecule chain length depending on the threshold voltage of the semiconductor element out of a plurality of materials of which each molecule chain length differs, in the film formation step the characteristic control layer be formed from the material selected in the material selection step. According to this embodiment, as compared with the method of adjusting the threshold voltage only based on the density, the threshold voltage can be adjusted more precisely.

The semiconductor element concerning the invention is manufactured by the manufacturing method of each of the embodiments described above. That is, according to a second aspect of the invention, this semiconductor element includes: an organic-semiconductor layer facing to a gate electrode across an insulating layer; and a characteristic control layer interposed in between the insulating layer and the organic-semiconductor layer, the characteristic control layer being formed in a density as of prior to the saturation, the density corresponding to the threshold voltage of the semiconductor element, the characteristic control layer being formed from a predetermined material of which density is saturated as the film formation proceeds. This semiconductor element, because the threshold voltage is precisely adjusted depending on the density of the characteristic control layer, is especially suitable, for example, as switching elements in apparatuses in which a precise switching characteristic is required.

Moreover, according to a third aspect of the invention, a semiconductor device includes first and second semiconductor elements, each having an organic-semiconductor layer facing to a gate electrode across an insulating layer and a characteristic control layer formed in between the insulating layer and the organic-semiconductor layer, the characteristic control layer being formed from a predetermined material of which density is saturated as the film formation proceeds.

The characteristic control layer of the first semiconductor element is formed in a density as of prior to the saturation, the density corresponding to the threshold voltage of the semiconductor element, the density being different from that of the characteristic control layer of the second semiconductor element, and the threshold voltage of the first semiconductor element differs from the threshold voltage of the second semiconductor element depending on this density difference. According to this configuration, a desired switching characteristic can be realized precisely by each of the semiconductor elements of which each threshold voltage is adjusted precisely.

### BRIEF DESCRIPTION OF THE DRAWINGS

The invention will be described with reference to the accompanying drawings, wherein like numbers refer to like elements.

FIG. 1 is a sectional view showing a structure of a semiconductor element.

FIG. 2 is a sectional view showing a step in which an insulating layer is formed.

FIG. 3 is a sectional view showing a step in which a source electrode and a drain electrode are formed.

FIG. 4 is a sectional view showing a step in which a characteristic control layer is formed.

FIG. 5 is a graph showing a relationship between the degree of growth, density, and film thickness of the characteristic control layer.

FIG. 6 is a view for explaining the measurement of the film thickness of the characteristic control layer.

FIG. 7 is a view for explaining a water contact angle in the surface of the characteristic control layer.

FIG. 8 is a graph showing a relationship between the voltage VG and the current ID for each density of the characteristic control layer.

FIG. 9 is a graph showing a relationship between the voltage VG and the current ID for each density of the characteristic control layer.

FIG. 10 is a graph showing a situation of variation of the density when heating the characteristic control layer.

FIG. 11 is a graph showing a situation of variation of the density when soaking the characteristic control layer into a density control solution.

FIG. 12 is a graph showing a relationship between the voltage VG and the current ID for each molecule chain length of the characteristic control layer.

FIG. 13 is a graph showing a relationship between the voltage VG and the current ID for each molecule chain length of the characteristic control layer.

FIG. 14 is a sectional view showing the configuration of a semiconductor element in a semiconductor device concerning a third embodiment.

FIG. 15 is a sectional view showing the configuration of a semiconductor element concerning a modification.

FIG. 16 is a sectional view showing the configuration of a semiconductor element concerning a modification.

### DESCRIPTION OF THE EMBODIMENTS

### A: First Embodiment

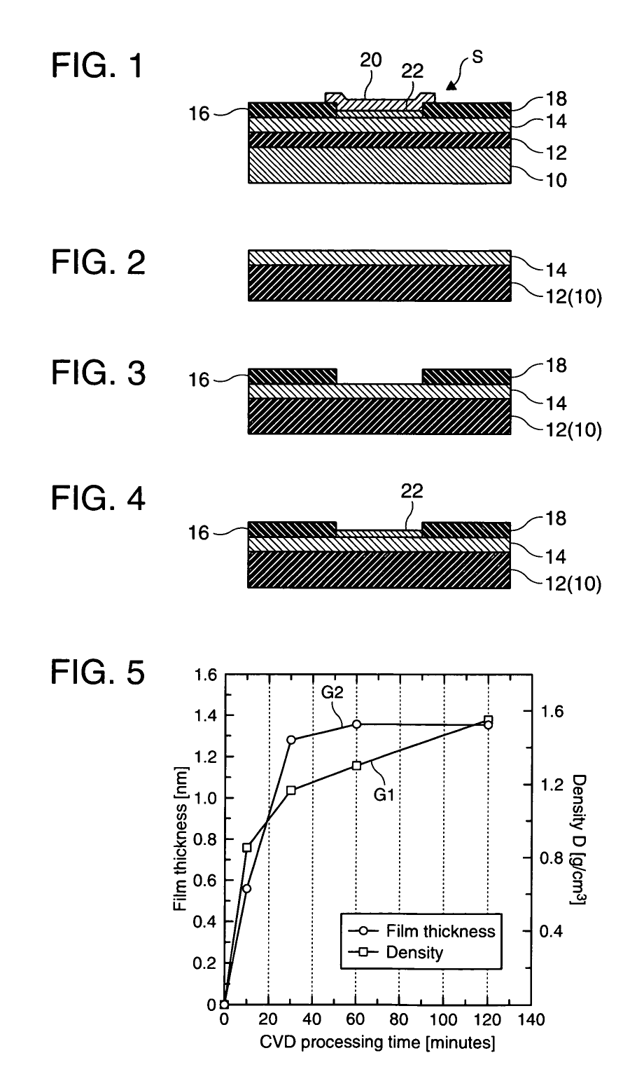

Structure of a Semiconductor Element FIG. 1 is a sectional view showing the structure of a semiconductor element concerning this embodiment. As shown in this view, a semiconductor element S includes: a gate electrode 12 formed in the surface of a substrate 10; an insulating layer 14 formed in the surface of the gate electrode 12; a source electrode 16 and a drain electrode 18 formed in the surface of the insulating layer 14; a semiconductor layer 20 formed from an organic-semiconductor material as to face to the gate electrode 12 across the insulating layer 14; and a characteristic control layer 22 interposed in between the semiconductor layer 20 and the insulating layer 14. That is, the semiconductor layer 20 in this embodiment is a field-effect transistor (a thin film transistor) of an insulated-gate structure (especially, MIS (Metal Insulator Semiconductor) structure in this embodiment) in which a channel is induced in the semiconductor layer 20 depending on the potential of the gate electrode 12.

The characteristic control layer 22 shown in FIG. 1 is a film for adjusting the threshold voltage Vth of the semiconductor element S. In this embodiment, the threshold voltage Vth is adjusted by controlling the density D of this characteristic control layer 22. According to this configuration, the threshold voltage Vth can be adjusted precisely, without changing the material of the semiconductor layer 20.

Manufacturing Method of Semiconductor Element S

Next, a specific example of the method for manufacturing the semiconductor element S will be described. However, the material, size, and formation method of each part of the semiconductor element S are not restricted to the following illustrations at all.

First, the substrate 10 is prepared. As this substrate 10, for example, a p type or n type single crystal silicon plate into which impurities, such as boron (B), phosphorus (P), and antimony (Sb), are doped, a hard plate made of glass or quartz, or a flexible plate made of plastics, such as polymethyl methacrylate, polyether sulfone, and polycarbonate, are used. In this embodiment, a case is illustrated in which a single crystal silicon plate into which doping of impurities is carried out is used as the substrate 10. In this case, the substrate 10 is used as the gate electrode 12.

Next, as shown in FIG. 2, the insulating layer 14 is formed in the surface of the gate electrode 12 (the substrate 10). The insulating layer 14 in this embodiment is a film of SiO₂ formed by means of the thermal oxidation of the surface of the substrate 10. However, the method of forming the insulating layer 14 is optional. For example, the insulating layer 14 made of insulators, such as SiO₂ and aluminum Al₂O₃, may be formed with a vacuum film formation method, such as a sputtering method and a CVD (Chemical Vapor Deposition) method. The film thickness of the insulating layer 14 is in the range from 100 nm to 800 nm.

Subsequently, as shown in FIG. 3, a source electrode 16 and a drain electrode 18 are formed in the surface of the insulating layer 14. The material of the source electrode 16 and drain electrode 18 is, for example, an electrical conductive material, such as various kinds of metals or metal oxides, or carbon. In the case where the semiconductor layer 20 is formed from fullerene (C₆₀), material, such as platinum (Pt), gold (Au), silver (Ag), copper (Cu), aluminum (Al), indium tin oxide (ITO), is suitable as the material of the source electrode 16 and drain electrode 18. The source electrode 16 and drain electrode 18 are produced by patterning a film into a desired shape by means of a lithography technique and etching technique, the film being formed in the film thickness of approximately 50 nm to 300 nm in the surface of the insulating layer 14 by means of a vacuum film formation method.

Next, as shown in FIG. 4, a characteristic control layer 22 is formed in the surface of the insulating layer 14 exposed in a gap in between the source electrode 16 and the drain electrode 18. A characteristic value (for example, the density D) of this characteristic control layer 22 is controlled so that the threshold voltage Vth of the semiconductor element S becomes a predetermined value. A relationship between the characteristic value and the threshold voltage Vth of this characteristic control layer 22, and a method of controlling the characteristic of the characteristic control layer 22 will be described later.

The characteristic control layer 22 is formed, for example, by means of a vacuum film formation method, such as a sputtering method or a CVD method, or a film forming method (a coating technique) using a liquid phase, such as a spin coating method, a dipping method (a free coating method). Moreover, the patterning of the characteristic control layer 22 is carried out with a lithography technique or etching technique as required.

The characteristic control layer 22 in this embodiment is formed from a material, the characteristic value of which (for example, the density D) is saturated to a substantially constant value as the film formation proceeds, and which is, for example, a self-assembled monolayer (SAM) formed with a self-assembly (SA: Self-Assembly) method. As this self-assembled monolayer, a silane compound expressed as a general formula of, for example, R¹ (CH₂) ₘSiR²ₙX₃₋ₙ may be used (m is a natural number, n=0, 1 and 2). The terminal group R¹ of this silane compound is hydrogen (—H), fluorine (—F), a methyl group (—CH₃), a trifluoromethyl group (—CF₃), an amino group (—NH₂), or a mercapto group (—SH). On the other hand, the X group is halogen or an alkoxy group. This kind of X group adheres chemically to the surface of the insulating layer 14 made of SiO₂, Al₂O₃, or the like through a hydrolysis reaction, thereby forming a hard and dense monolayer. In the surface of the characteristic control layer 22 formed in this way, the terminal group R¹ is disposed regularly.

After the characteristic control layer 22 is formed through the above steps, as shown in FIG. 1 the semiconductor layer 20 is formed as to face to the gate electrode 12 across the characteristic control layer 22 and insulating layer 14. This semiconductor layer 20 is produced patterning a film by using a lithography technique and etching technique, the film being formed, for example, by means of a molecular beam vapor depositing method (MBE method), a spin coating method, or a cast method. Moreover, the semiconductor layer 20 in a desired shape may be formed by causing an organic-semiconductor material selectively to adhere onto the surface of the substrate 10 by means of a mask film forming method or an ink-jet method (a droplet-discharging method). The semiconductor layer 20 is formed from at least one kind selected from, for example, a low molecule organic material, such as pentacene and oligothiophene; a high molecule organic material, such as poly thiophene; a metal complex, such as phthalocyanine; a type of fullerene, such as C₆₀, or C₇₀, and a metal contained fullerene (for example, a dysprosium contained fullerene); and an organic-semiconductor material such as a type of carbon nanotubes.

Relationship between the density D of the characteristic control layer 22, and the threshold voltage Vth of the semiconductor element S As the results of various experiments concerning organic-semiconductor materials, the present inventor obtained a knowledge that the threshold voltage Vth of the semiconductor element S varies depending on the density D of the characteristic control layer 22. The results of these experiments will be described in detail hereinafter.

As for the characteristic control layer 22, which is a self-assembled monolayer made of a silane compound, various kinds of characteristic values vary depending on the extent of processing of the film formation (hereinafter, referred to as the “film formation progress”). The results of the experiment regarding the variations of this characteristic value will be described hereinafter. In addition, the samples used for this experiment are the ones in which the surface of an N type single-crystal substrate (the gate electrode 12) is oxidized by heating, thereby to form the insulating layer 14 of 300 nm, and the drain electrode 18 and source electrode 16 in the film thickness of approximately 100 nm are formed from gold (Au) in the surface of this insulating layer 14. The characteristic values (here, the density, film thickness, and contact angle) of the characteristic control layer 22 are measured while the characteristic control layer 22, which is made of a silane compound of a chemical formula called CF₃(CF₂)₇(CH₂)₂Si (OC₂H₅)₃, is film-formed in the surface of the insulating layer 14 of this sample by means of a CVD method. The temperature of the substrate 10 during the film formation is approximately 110° C.

(1) Density

The characteristic G1 of FIG. 5 is a graph showing a relationship between the extent of the growth of the characteristic control layer 22 and the density D thereof. In this view, the elapsed time (the CVD processing time), with the start point of the film formation by a CVD method being set to “0”, is shown on the horizontal axis as an index showing the film formation progress, and the density D (g/cm³) of the characteristic control layer 22 is shown on the vertical axis. As shown in this view, the density D of the characteristic control layer 22 increases along with the progress of the film formation at the beginning when the film formation is started, however, after the progress reaches a specific phase, the density D maintains a substantially constant value (approximately, 1.6 g/cm³) (i.e., is saturated). Therefore, in the state of before the density D is saturated, the density D of the characteristic control layer 22 can be controlled arbitrarily depending on the film formation progress.

(2) Film Thickness

The characteristic G2 of FIG. 5 is a graph showing a relationship between the CVD processing time of the characteristic control layer 22 and the film thickness thereof. As to this characteristic G2, the film-thickness (nm) of the characteristic control layer 22 is shown on the vertical axis. As shown in this view, the film thickness of the characteristic control layer 22 increases along with the progress of the film formation at the beginning when the film formation is started, however, once the progress reaches a specific phase, the film thickness is saturated to a substantially constant value (approximately, 1.4 nm). Therefore, in the state of prior to the saturation, the film thickness of the characteristic control layer 22 can be controlled arbitrarily depending on the film formation progress. In addition, a time point when the film thickness of the characteristic control layer 22 begins to be saturated with respect to the film formation progress is considered to be a time point when the terminal group R¹, such as a trifluoromethyl group and a methyl group, has been disposed regularly in the surface of the characteristic control layer 22. Namely, the film thickness of the characteristic control layer 22 is saturated in this phase, because the terminal group R¹ is disposed in the surface, whereby highly reactive portions (X group and R² group) are not exposed to the surface anymore.

In addition, in the above experiment, the film thickness of the characteristic control layer 22 was measured with an X-ray reflection factor measuring method. The principle of this X-ray reflection factor measuring method and the principle of measuring the film thickness based on this will be described hereinafter.

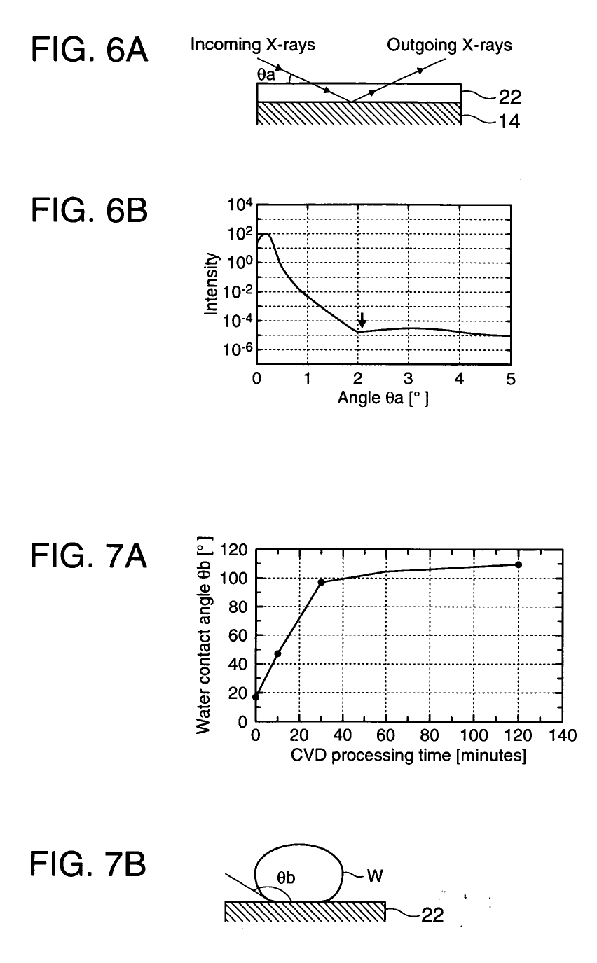

As shown in FIG. 6A, X-rays irradiated from the direction of an elevation angle θₐ with respect to the surface of the characteristic control layer 22 is divided into component that scatters and reflects in the surface of this characteristic control layer 22, and the component incident on the inside of the characteristic control layer 22. Furthermore, the X-rays incident on the inside of the characteristic control layer 22 is divided into the component that scatters and reflects in the interface between the characteristic control layer 22 and the insulating layer 14, and the component incident on the inside of the insulating layer 14. Then, because the X-rays that reflect in each interface interfere to each other depending on the film thickness of the characteristic control layer 22, the X-rays outgoing from the sample (hereinafter, referred to as the “outgoing X-rays”) will have an intensity depending on the angle θₐ and the film thickness of the characteristic control layer 22. Therefore, the film thickness of the characteristic control layer 22 can be measured by measuring and analyzing the intensity of the outgoing X-rays.

FIG. 6B is a graph showing a relationship between the angle θₐ of X-rays, and the intensity (an arbitrary scale) of the outgoing X-rays. As shown in this view, the intensity of the outgoing X-rays decreases along with the increase of the angle θₐ and maintains a substantially constant value once the angle θₐ exceeds a specific value. In this way, based on the angle θₐ (the angle designated by the arrow in FIG. 3B) at the time when the intensity of the outgoing X-rays begins to remain substantially constant, the film thickness of the characteristic control layer 22 can be calculated.

(3) Wettability

Next, FIG. 7A is a graph showing a relationship between the CVD processing time of the characteristic control layer 22, and the contact angle θ_{b} of water in the surface thereof (hereinafter, referred to as the “water contact angle”). In this view, the CVD processing time is shown on the horizontal axis like FIG. 5, and the water contact angle θ_{b} (°) is shown on the vertical axis. In addition, as shown in FIG. 7B, the water contact angle θ_{b} is the elevation angle between the surface of a water drop W dropped in the surface of the characteristic control layer 22 and the surface of the characteristic control layer 22. As shown in FIG. 7A, the water contact angle θ_{b} of the characteristic control layer 22 increases along with the progress of the film formation at the beginning when the film formation is started, however, the water contact angle is saturated to a substantially constant value (approximately 110°) once the progress reaches a specific phase.

As described above, the density, film thickness, and water contact angle of the characteristic control layer 22 are saturated to be substantially constant once the progress reaches a specific phase. Then, the film formation progress at the time when these characteristics are saturated is substantially constant. For example, according to the results of the experiments described above, each characteristic value is saturated to a substantially constant value in the phase where the CVD processing time exceeds approximately 60 minutes. Accordingly, if the relationship between the film formation progress (especially, the film formation progress at the time when the film thickness and water contact angle are saturated), and the film thickness and the water contact angle of the characteristic control layer 22 is measured in advance, the characteristic control layer 22 of various densities D in a preliminary phase of before the characteristic value is saturated can be produced quantitatively.

Next, the results of the measured relationship between the density D of the characteristic control layer 22 and the threshold voltage Vth of the semiconductor element S will be described. The target for this measurement is the one in which the semiconductor layer 20 made of pentacene (C₂₂H₁₄) is formed in the surface of the characteristic control layer 22 of the sample described above. This semiconductor layer 20 was formed with a vacuum evaporation method in which the speed of vapor deposition is set to 0.15 A/s. The degree of vacuum is 1×10⁻⁶ torr and the temperature of the substrate 10 is 25° C. during the film formation.

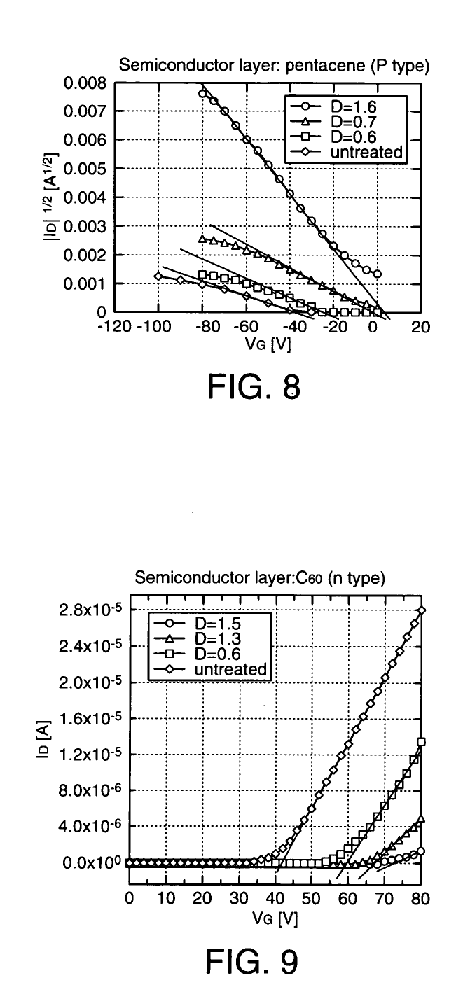

FIG. 8 is a graph showing the electric characteristic of the semiconductor element S in the case where the voltage VD between the source electrode 16 and the drain electrodes 18 is set to 80V for each density D of the characteristic control layer 22. In this view, the voltage VG (V) of the gate electrode 12 on the basis of the potential of the drain electrode 18 is shown on the horizontal axis, and a square root of current ID flowing between the source electrode 16 and the drain electrode 18 is shown on the vertical axis. In FIG. 8, there is shown each characteristic of the semiconductor element S in which the density D of the characteristic control layer 22 is set to 1.6 g/cm³, 0.7 g/cm³, and 0.6 g/cm³, respectively. Moreover, in this view, the characteristic (untreated) of a semiconductor element with a structure in which the characteristic control layer 22 is not formed (namely, a structure in which the insulating layer 14 comes in contact with the semiconductor layer 20) is illustrated together for reference.

As shown in FIG. 8, the electric characteristic (the switching characteristic) of the semiconductor element S differs depending on the density D of the characteristic control layer 22. Here, as shown in FIG. 8, assuming a straight line which approximates the portion in which a square root of the current ID varies linearly with respect to the voltage VG out of the each characteristic, the voltage VG at the intersection of this straight line and the horizontal axis (ID=0) corresponds to the threshold voltage Vth of the semiconductor element S. Accordingly, the relationship between the density D of the characteristic control layer 22 and the threshold voltage Vth is identified as follows:

(a) D=1.6 [g/cm³]: Vth≅5 [V]

(b) D=0.7 [g/cm³]: Vth≅−5 [V]

(c) D=0.6 [g/cm³]: Vth≅−30 [V]

(d) Untreated (without the characteristic control layer): Vth≅−40 [V]

That is, the threshold voltage Vth of the semiconductor element S increases as the density D of the characteristic control layer 22 increases. This result shows that the threshold voltage Vth of the semiconductor element S can be precisely adjusted by controlling the density D of the characteristic control layer 22.

On the other hand, FIG. 9 is a graph showing a relationship between the voltage VG and the current ID in the case where the semiconductor layer 20 is formed from C₆₀, which is an n type semiconductor material. In this measurement, the voltage VD (the voltage between the source electrode 16 and the drain electrodes 18) is set to 5V. Moreover, the semiconductor layer 20 was formed with a molecular-beam vapor-depositing method (an MBE method), in which the speed of vapor deposition was set to 0.15 A/s. The degree of vacuum is 1×10⁻⁹ torr and the temperature of the substrate 10 is 100° C. during the film formation. As shown in this view, the threshold voltage Vth is approximately 55V when the density D of the characteristic control layer 22 is set to 0.6 g/cm³, the threshold voltage Vth is approximately 65V when the density D is set to 1.3 g/cm³, and the threshold voltage Vth is approximately 70V when the density D is set to 1.5 g/cm³. That is, also in the structure in which the semiconductor layer 20 is formed from C₆₀, it is apparent that the threshold voltage Vth of the semiconductor element S increases as the density D of the characteristic control layer 22 becomes higher. Accordingly, also in this structure, the threshold voltage Vth of the semiconductor element S can be precisely adjusted by controlling the density D of the characteristic control layer 22.

Based on the results of the above experiments, in the step shown in FIG. 4, after the density D depending on the threshold voltage Vth of the semiconductor element S is selected, the characteristic control layer 22, which is in the state of prior to the saturation with respect to the film formation progress, is formed as to be in the relevant density D. According to this method, the threshold voltage Vth can be adjusted precisely, without changing the material of the semiconductor layer 20.

Method for controlling the density D of the characteristic control layer Next, a specific method for controlling the density D of the characteristic control layer 22 will be described. As described above, because the density D of the characteristic control layer 22 is saturated to a substantially constant value if the film formation progress reaches a specific phase, the characteristic control layer 22 in the state of not having reached the saturation state (hereinafter, referred to as the “non-saturation state”) needs to be produced in order to control the density D as to correspond to a desired threshold voltage Vth. As the method for producing the characteristic control layer 22 of this non-saturation state, there are: a method in which the film formation is terminated in an intermediate phase (namely, in the phase of before reaching the saturation state) during the process of film-forming the characteristic control layer 22 (hereinafter, referred to as the “first density control method”); and a method in which after allowing the film formation to have proceeded until it reaches the saturation state once, a predetermined treatment is applied to the characteristic control layer 22 thereby to reduce the density D (hereinafter, referred to as the “second density control method”). The specific example of each method will be described hereinafter.

(1) First Density Control Method

In the first density control method, the film formation is terminated in a phase of prior to the phase of reaching the saturation state (hereinafter, referred to as the “saturation start point”) during the process of film-forming the characteristic control layer 22. This saturation start point is identified by experimentally measuring the relationship between the film formation progress of the characteristic control layer 22, and the density D of the characteristic control layer 22, in advance.

For example, in the case where the result like the characteristic G1 of FIG. 5 is obtained through a preliminary experiment, the saturation start point may be estimated as to be approximately 60 minutes. Accordingly, in this case, in the step for film-forming the characteristic control layer 22 among the steps of actually manufacturing the semiconductor element S, the characteristic control layer 22 with a desired density D can be formed by terminating the film formation at a time point before the CVD processing time passes through approximately 60 minutes from the start thereof.

However, it may be difficult to measure the density D of the characteristic control layer 22. In such a case, as described hereinafter, it is possible to estimate the saturation start point by measuring a relationship between a characteristic value other than the density D of the characteristic control layer 22 (for example, the film thickness and water contact angle of the characteristic control layer 22), and the film formation progress.

As shown as the characteristic G2 in FIG. 5, the film thickness of the characteristic control layer 22 made of a self-assembled monolayer of a silane compound increases along with the progress of the film formation at the beginning when the film formation is started, however, the film thickness is saturated at a substantially constant value if the film formation proceeds to a specific phase. This time point of starting to be saturated is substantially in agreement with the saturation start point of the density D of the characteristic control layer 22. Accordingly, if the time point when the film thickness is saturated is detected by measuring experimentally the relationship between the film formation progress and the film thickness of the characteristic control layer 22 in advance, it is possible to estimate this time point as the saturation start point of the density D. That is, in the step for actually forming the characteristic control layer 22, the characteristic control layer 22 with a desired density D can be formed by terminating the film formation in the phase of before the time point identified here elapses.

Moreover, as shown in FIG. 7A, the time point, when the water contact angle of the characteristic control layer 22 made of a self-assembled monolayer of a silane compound is saturated with respect to the progress of the film formation, is substantially in agreement with the saturation start point of the density D of the characteristic control layer 22. Accordingly, if the time point when the water contact angle is saturated is detected by measuring the relationship between the film formation progress and the water contact angle of the characteristic control layer 22 in advance, it is possible to estimate this time point as the saturation start point of the density D. Accordingly, in the step for actually forming the characteristic control layer 22, the characteristic control layer 22 with a desired density D can be formed by terminating the film formation in the phase of before the time point identified here elapses.

(2) Second Density Control Method

In the second density control method, a predetermined treatment is applied to the characteristic control layer 22, in which the film formation proceeded to the saturation state once, thereby to reduce the density D. As the specific examples of this treatment, there are a treatment of heating the characteristic control layer 22, a treatment of irradiating light at the characteristic control layer 22, and a treatment of soaking the characteristic control layer 22 into a predetermined liquid (hereinafter, referred to as the “density control medical fluid”). The specific contents of these treatments will be described hereinafter. In addition, a plurality of treatments shown hereinafter may be carried out in combination.

(a) Treatment of Heating the Characteristic Control Layer 22

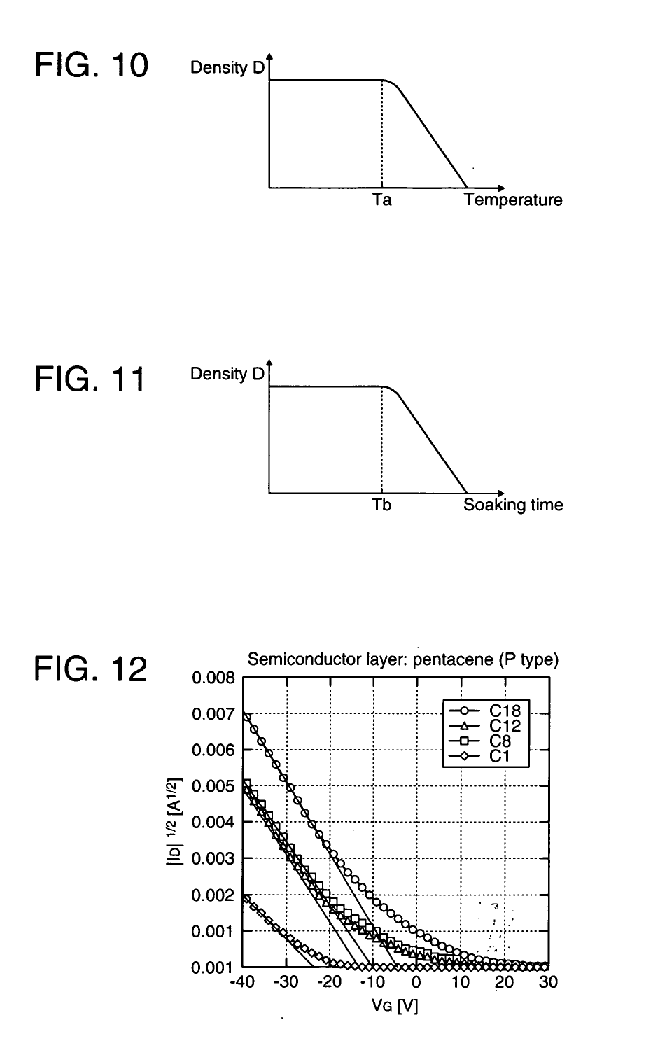

FIG. 10 is a graph showing a situation of variations of the density D when the characteristic control layer 22 in the saturation state is heated. In this view, the temperature of the characteristic control layer 22 at the time of heating is shown on the horizontal axis, and the density D of the characteristic control layer 22 is shown on the vertical axis. As shown in this view, the density D of the characteristic control layer 22 in the saturation state maintains a substantially constant value if the temperature is lower than a predetermined value Ta shown in FIG. 10, however, if heated to temperatures higher than the predetermined value Ta, it decreases continuously depending on the temperature thereof. Accordingly, by heating the characteristic control layer 22, which was caused to be in the saturation state once, to a temperature higher than the predetermined value Ta, the density D of the characteristic control layer 22 can be controlled to a desired value depending on the temperature thereof In addition, although in FIG. 10 the variation of the density D with respect to the temperature of the characteristic control layer 22 is illustrated, the density D of the characteristic control layer 22 also varies in the same way depending on the heating time. Accordingly, the density D may be controlled by adjusting the heating time of the characteristic control layer 22.

(b) Treatment of Irradiating Light at the Characteristic Control Layer 22

If light, such as ultraviolet rays, is irradiated at the characteristic control layer 22, which is in the saturation state, the density D will decrease corresponding to the irradiation time period, or the intensity or the wavelength of light. That is, the density D of the characteristic control layer 22 decreases greatly as the time period when light is irradiated becomes longer, the density D of the characteristic control layer 22 decreases greatly as the intensity of light becomes higher and the wavelength becomes shorter, and the like. Accordingly, the density D of the characteristic control layer 22 can be controlled to a predetermined value by irradiating light corresponding to the desired density D at the characteristic control layer 22, which was caused to be in the saturation state once, over a suitable time period.

(c) Treatment of Soaking into a Density Control Medical Fluid

FIG. 11 is a graph showing a situation of variation of the density D when the characteristic control layer 22 in the saturation state is soaked into an alkaline density control medical fluid. In this view, the soaking time is shown on the horizontal axis, and the density D of the characteristic control layer 22 is shown on the vertical axis. As shown in this view, the density D of the characteristic control layer 22 in a saturation state decreases, if the time period of being soaked into a density control medical fluid exceeds a predetermined value Tb, continuously depending on the time thereof. Accordingly, by soaking the characteristic control layer 22, which was caused to be in the saturation state once, into the density control medical fluid over a time period longer than the predetermined value Th, the density D of the characteristic control layer 22 can be controlled to a desired value depending on the soaking time thereof. The pH of the density control medical fluid used in this treatment is preferably 10 to 12, and the specific example includes a solution of tetramethyl ammonium hydroxide (TMAH), or sodium hydroxide (NaOH) and potassium hydroxide (KOH), or the like. In addition, although in FIG. 11 the variation of the density D with respect to the time period of being soaked into the density control medical fluid is illustrated, the density D of the characteristic control layer 22 varies in the same way depending on the pH of the density control medical fluid. Accordingly, the density D of the characteristic control layer 22 may be controlled by adjusting the pH of the density control medical fluid.

According to the second density control method described above, because the density D of the characteristic control layer 22 in each of a lot of semiconductor elements S formed in the surface of the substrate 10 can be individually adjusted as compared with the first density control method, there is an advantage that a plurality of semiconductor elements S of which each threshold voltage Vth differs can be produced easily. On the other hand, according to the first density control method, because the density D of the characteristic control layer 22 can be adjusted with a simple and short time treatment as compared with the second density control method, in which treatments such as heating and photo-irradiation are carried out after being film-formed to the saturation state once, the manufacturing cost of the semiconductor element S can be reduced.

### B: Second Embodiment

Next, a second embodiment of the invention will be described. In the first embodiment, a configuration is illustrated in which the threshold voltage Vth is adjusted by controlling the density D of the characteristic control layer 22. In this embodiment, in addition to the adjustment of the threshold voltage Vth depending on this density D, the threshold voltage Vth is adjusted depending on a molecule chain length of the material of the characteristic control layer 22. In addition, common reference numerals are given to the same elements as those of the first embodiment among these embodiments, and the description thereof will be omitted suitably.

FIG. 12 is a graph showing a relationship between the voltage VG applied to the gate electrode of the semiconductor element S in this embodiment, and the current ID (a square root of the current ID, here) flowing between the source electrode 16 and the drain electrodes 18. In this view, assume a case where a semiconductor layer 20 is formed from pentacene, which is a p type organic-semiconductor material, and the voltage VD between the source electrode 16 and the drain electrode 18 is set to 80 V. In addition, the size of each part of the semiconductor element S and the conditions during the formation are as shown in the first embodiment.

Each characteristic illustrated together in FIG. 12 is the characteristic of the semiconductor element S, in which the characteristic control layer 22 is formed from each of four kinds of silane compounds of which molecule chain length differs. These silane compounds are compounds in which terminal group R¹, R² group and the X group in the general formula described above are in common and each molecule chain length (a natural number m) differs. The chemical formula of each compound is as follows:

(a) [(CH₃) ₃Si]₂NH (the characteristic “C1” in FIG. 12, and hereinafter, referred to as the “C1 compound”)

(b) CH₃(CH₂)₇Si(OC₂H₅)₃ (the characteristic “C8” in FIG. 12, and hereinafter, referred to as the “C8 compound”)

(c) CH₃(CH₂)₁₁Si(OC₂H₅)₃ (the characteristic “C12” in FIG. 12, and hereinafter, referred to as the “C12 compound”)

(d) CH₃(CH₂)₁₇Si(OC₂H₅)₃ (the characteristic “C18” in FIG. 12, and hereinafter, referred to as the “C18 compound”)

As shown in this view, depending on the molecule chain length of the material of the characteristic control layer 22, the electric characteristic (the switching characteristic) of the semiconductor element S differs. In FIG. 12, like FIG. 8, the intersection of the straight line approximating the linear portion of each characteristic and the horizontal axis (ID=0) corresponds to the threshold voltage Vth. From the graph of FIG. 12, the threshold voltage Vth of the semiconductor element S using each silane compound is identified as follows:

(a) C1 compound: Vth≅−23[V]

(b) C8 compound: Vth≅−13[V]

(c) C12 compound: Vth≅−10[V]

(d) C18 compound: Vth≅−5[V]

That is, the threshold voltage Vth of the semiconductor element S increases as the molecule chain length of the silane compound constituting the characteristic control layer 22 becomes longer. From this result, it is apparent that the threshold voltage Vth of the semiconductor element S can be adjusted precisely by selecting suitably the molecule chain length of the material to be the characteristic control layer 22.

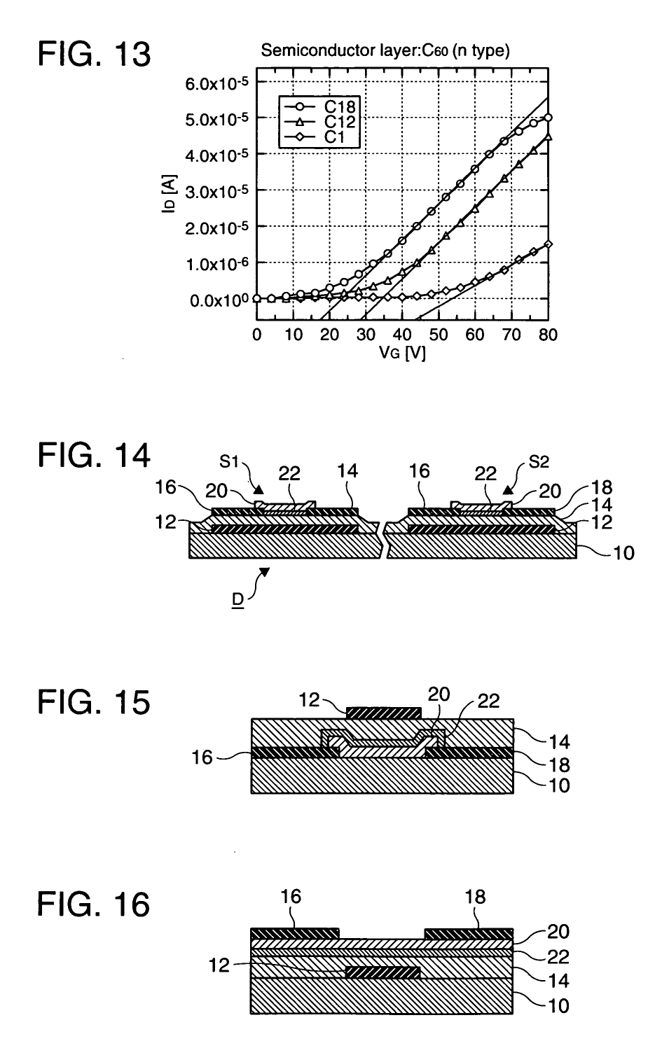

Next, FIG. 13 is a graph showing a relationship between the voltage VG and the current ID for each molecule chain length of the material of the characteristic control layer 22 in the case where the voltage VD is set to 5V after forming the semiconductor layer 20 from C₆₀, which is an n type semiconductor material. In addition, the size of each part of the semiconductor element S and the conditions during the formation are as shown in the first embodiment. In this view, the characteristic of C1 compound, the characteristic of C12 compound, and the characteristic of C18 compound are illustrated together. As shown in this view, in the configuration, in which the semiconductor layer 20 is an n type, the threshold voltage Vth becomes smaller as the molecule chain length of the material forming the characteristic control layer 22 becomes longer. Accordingly, also in this structure, the threshold voltage Vth can be precisely adjusted by selecting suitably the molecule chain length of the material of the characteristic control layer 22.

Based on the above results, in this embodiment, the material with the molecule chain length corresponding to a desired threshold voltage Vth is selected out of a plurality of materials of which each molecule chain length differs, and the characteristic control layer 22 is formed from this material. The density D of the characteristic control layer 22 is controlled depending on the threshold voltage Vth, as described in the first embodiment. That is, the threshold voltage Vth of the semiconductor element S is adjusted depending on the molecule chain length of the material of the characteristic control layer 22 and the density D thereof. According to this embodiment, as compared with the case where only the density D of the characteristic control layer 22 is adjusted, the threshold voltage Vth can be adjusted more precisely.

### C: Third Embodiment

Next, a semiconductor device using the semiconductor element S concerning each of the embodiments will be described. This semiconductor device is, for example, a display panel (for example, an active-matrix liquid crystal panel) in which the semiconductor elements S of each embodiment are used as switching elements that are formed for each pixel in order to control the voltage to be applied to the pixel, and as switching elements of a driver circuit for driving the pixel. However, the configuration and application of the semiconductor device are modified arbitrarily.

As shown in FIG. 14, in this semiconductor device D, a first semiconductor element S1 and a second semiconductor element S2 of which each threshold voltage Vth differs are formed in the surface of the single substrate 10. The first semiconductor element S1 is, for example, a switching element that is formed for each pixel in order to control the voltage to be applied to the pixel, and the second semiconductor element S2 is, for example, a switching element for the driver circuit. The respective configurations of the first semiconductor element S1 and the second semiconductor element S2 are the same as that of the semiconductor element S shown in FIG. 1. In this embodiment, assume a case where each semiconductor layer 20 of the first semiconductor element S1 and second semiconductor element S2 is formed from pentacene.

The density D1 of the characteristic control layer 22 in the first semiconductor element S1 is higher than the density D2 of the characteristic control layer 22 in the second semiconductor element S2. Accordingly, as described with reference to FIG. 8, the threshold voltage Vth1 of the first semiconductor element S1 is higher than the threshold voltage Vth2 of the second semiconductor element S2. In other words, the density D1 and density D2 may be selected individually so that the threshold voltage Vth1 becomes higher than the threshold voltage Vth2. Regarding this configuration, a configuration may be made in which the characteristic control layers 22 of the both first semiconductor element S1 and second semiconductor element S2 is in the non-saturation state, or a configuration may be made in which the characteristic control layer 22 of the first semiconductor element S1 is in the saturation state while the characteristic control layer 22 of the second semiconductor element S2 is in the non-saturation state. Moreover, as described as the second embodiment, by forming the characteristic control layer 22 of the first semiconductor element S1, and the characteristic control layer 22 of the second semiconductor element S2 from silane compounds of which molecule chain length differs, each threshold voltage Vth may be caused to differ.

Then, as shown in FIG. 14, in the case where a plurality of semiconductor elements S in which the density D of the characteristic control layer 22 differs are formed in batches in the surface of the substrate 10, it is difficult to adjust individually the density D of the characteristic control layer 22 of each semiconductor element S by means of the first density control method, in which the terminating point of the film formation of the characteristic control layer 22 is adjusted based on a desired threshold voltage Vth. Accordingly, in manufacturing the configuration shown in FIG. 14, the second density control method is suitably adopted, in which the density D of the characteristic control layer 22, which was caused to be in the saturation state once, is reduced by means of a predetermined treatment. That is, after film-forming the characteristic control layer 22 of all the semiconductor elements S on the substrate 10 to the saturation state under the same conditions, a treatment of reducing the density D is carried out selectively to these semiconductor elements S. For example, after coating the semiconductor element S1 with a light-shielding mask, light may be irradiated selectively only to the semiconductor element S2 thereby to reduce the density D. In this way, the second density control method illustrated as a method of controlling the density D of the characteristic control layer 22 is specially suitable in the case where a plurality of semiconductor element S of which each threshold voltage Vth differs are formed in the single substrate 10.

D: Modification

Various modifications may be applied to each embodiment. Specific modified embodiments will be illustrated hereinafter. In addition, each embodiment shown below may be combined suitably.

(1) Modification 1

As shown in FIG. 15, the positional relationship between the semiconductor layer 20 and the gate electrode 12 shown in FIG. 1 may be reversed. In the configuration of FIG. 15, the characteristic control layer 22 is formed in the surface of the semiconductor layer 20 formed in the substrate 10, and the gate electrode 12 is formed as to face to the semiconductor layer 20 across the insulating layer 14 that covers the semiconductor layer 20 and characteristic control layer 22. According to this configuration, there is an advantage that the flexibility in the choice of the material that forms the substrate 10 is high as compared with the configuration of FIG. 1, in which the gate electrode 12 and insulating layer 14 are formed in the surface of the substrate 10.

Moreover, as shown in FIG. 16, the source electrode 16 and the drain electrode 18 may be formed in the surface of the semiconductor layer 20. According to this configuration, the mobility of carriers can be improved because the influence from the source electrode 16 and drain electrode 18 on the semiconductor layer 20 can be reduced as compared with the configuration shown in FIG. 1.

(2) Modification 2

In each embodiment there have been illustrated methods in which the threshold voltage Vth of the semiconductor element S is adjusted depending on the density D and the molecule chain length of the characteristic control layer 22, however, in addition to this, by controlling other characteristic of the characteristic control layer 22 the threshold voltage Vth may be adjusted. For example, also by selecting the film thickness and material of the characteristic control layer 22 suitably, the threshold voltage Vth can be adjusted to a predetermined value.

(3) Modification 3

In each embodiment, although there have been illustrated the configurations in which the characteristic control layer 22 is formed across the whole region where the insulating layer 14 and semiconductor layer 20 face to each other, a configuration may be made in which the characteristic control layer 22 is formed selectively only in a specific portion of the above region if the desired switching characteristic regarding the semiconductor element S is obtained. Moreover, if there is no practical problem in the switching characteristic of the semiconductor element S, the characteristic control layer 22 may be formed in portions other than the region where the insulating layer 14 and semiconductor layer 20 face to each other (for example, in the surface of the source electrode 16 or the drain electrode 18).

What is claimed is:

1. A method for manufacturing a semiconductor element in which a characteristic control layer for controlling a threshold voltage of the semiconductor element interposed in between an organic-semiconductor layer facing to a gate electrode across an insulating layer, and the insulating layer, the method comprising:
selecting a density of the characteristic control layer depending on a threshold voltage of the semiconductor element; and
forming the characteristic control layer of the density selected in the selection step.

2. The method for manufacturing a semiconductor element according to claim 1, wherein in the film formation step, the characteristic control layer of the density as of prior to saturation is formed from a predetermined material of which density is saturated as the film formation proceeds.

3. The method for manufacturing a semiconductor element according to claim 2, wherein in the film formation step, the film formation is terminated in a phase of before the density of the characteristic control layer is saturated.

4. The method for manufacturing a semiconductor element according to claim 3, further comprising a measurement step for measuring a relationship between the extent of processing of film formation of a film made of the predetermined material, and a contact angle of liquid in the surface of the film, thereby detecting a specific phase in which the contact angle is saturated with respect to progress of the film formation,
wherein in the film formation step, the film formation is terminated prior to the specific phase detected in the measurement step.

5. The method for manufacturing a semiconductor element according to claim 3, further comprising a measurement step for measuring a relationship between the extent of processing of film formation of a film made of a predetermined material, and the film thickness of the film, thereby detecting a specific phase in which the contact angle is saturated with respect to progress of the film formation,
wherein in the film formation step, the film formation is terminated prior to the specific phase detected in the measurement step.

6. The method for manufacturing a semiconductor element according to claim 2, wherein the film formation step includes:
a first step for allowing the film formation to proceed until the density of the characteristic control layer is saturated; and
a second step for applying a treatment to reduce the density with respect to the characteristic control layer formed in the first step.

7. The method for manufacturing a semiconductor element according to claim 6, wherein the second step includes a step for heating the characteristic control layer formed by the first step, thereby reducing the density thereof.

8. The method for manufacturing a semiconductor element according to claim 6, wherein the second step includes a step for irradiating light at the characteristic control layer formed by the first step, thereby reducing the density thereof.

9. The method for manufacturing a semiconductor element according to claim 6, wherein the second step includes a step for soaking into an alkaline liquid the characteristic control layer formed by the first step, thereby reducing the density thereof.

10. The method for manufacturing a semiconductor element according to claim 1, further comprising a material selection step for selecting a material having a molecule chain length corresponding to a threshold voltage of the semiconductor element out of a plurality of materials of which each molecule chain length differs,
wherein in the film formation step, the characteristic control layer is formed from the material selected in the material selection step.

11. The method for manufacturing a semiconductor element according to claim 1, wherein in the film formation step, the characteristic control layer is formed from a silane compound as the predetermined material.

12. A semiconductor element, comprising:
an organic-semiconductor layer facing to a gate electrode across an insulating layer; and
a characteristic control layer interposed in between the insulating layer and the organic-semiconductor layer, the characteristic control layer being formed in a density as of prior to the saturation, the density corresponding to a threshold voltage of the semiconductor element, the characteristic control layer being formed from a predetermined material of which density is saturated as the film formation proceeds.

13. A semiconductor device, comprising first and second semiconductor elements each having an organic-semiconductor layer facing to a gate electrode across an insulating layer, and a characteristic control layer formed in between the insulating layer and the organic-semiconductor layer, the characteristic control layer being formed from a predetermined material of which density is saturated as the film formation proceeds,
wherein the characteristic control layer of the first semiconductor element is formed in a density as of prior to the saturation, the density corresponding to the threshold voltage of the semiconductor element, the density being different from that of the characteristic control layer of the second semiconductor element, and the threshold voltage of the first semiconductor element differs from the threshold voltage of the second semiconductor element according to this density difference.
